(19) United States
(12) Patent Application Publication
(10) Pub. No.: US 2026/0165097 A1
(43) Pub. Date: Jun. 11, 2026

(54) SEMICONDUCTOR DIE AND METHOD OF MANUFACTURING THE SAME

(71) Applicant: Infineon Technologies AG, Neubiberg (DE)

(72) Inventors: Thomas GANNER, Krumpendorf am Wörthersee (AT); Jochen HILSENBECK, Villach (AT); Thomas SÖLLRADL, Arnoldstein (AT); Tobias WASSERMANN, Soest, Hattrop (DE); Paul SALMEN, Ense, Bremen (DE); Philipp ROSS, München, Bayern (DE); Dethard PETERS, Höchstadt (DE); Andreas KORZENIETZ, Putzbrunn (DE); Konrad SCHRAML, Feldkirchen (DE)

(21) Appl. No.: 19/181,799

(22) Filed: Apr. 17, 2025

(30) Foreign Application Priority Data
Apr. 18, 2024 (DE) 102024203637.4
Nov. 20, 2024 (DE) 102024133996.9

(51) Int. Cl. H10W 10/10; H10W 10/00

(52) U.S. Cl. CPC H10W 10/10; H10W 10/011

(57) ABSTRACT

The disclosure relates to a semiconductor die, comprising a silicon carbide (SiC) semiconductor body; a passivation system on a first side of the SiC semiconductor body ; the passivation system comprising an inorganic passivation layer system and an organic layer on the inorganic passivation layer system, a lateral edge of the inorganic passivation layer system arranged on the SiC semiconductor body, wherein the inorganic passivation layer system is laterally set back under the organic layer, the lateral edge of the inorganic passivation layer system being covered by the organic layer.

### RELATED APPLICATION

This application claims priority to German Patent Application No. 102024203637.4, filed on Apr. 18, 2024, entitled “SEMICONDUCTOR DIE AND METHOD OF MANUFACTURING THE SAME”, which is incorporated by reference herein in its entirety. This application also claims priority to German Patent Application No. 102024133996.9, filed on Nov. 20, 2024, entitled “SEMICONDUCTOR DIE AND METHOD OF MANUFACTURING THE SAME”, which is incorporated by reference herein in its entirety.

### TECHNICAL FIELD

The present disclosure relates to a semiconductor die comprising a semiconductor body.

### BACKGROUND

In embodiments of this application, the semiconductor body is made of silicon carbide (SiC) which has a comparably wide band gap, e.g. compared to silicon. This can for instance be of interest for power semiconductor devices in high voltage and/or high current applications. In the semiconductor body, a device structure with a load terminal or terminals can be formed, for example a transistor structure having a source terminal and a drain terminal. For a wiring and contacting of the device structure, a metallization can be formed on the semiconductor body.

### SUMMARY

Examples of the present application are directed at an advantageous semiconductor die.

The semiconductor die may comprise a silicon carbide (SiC) semiconductor body, an insulating layer and a passivation system with an inorganic passivation layer system. The insulating layer is arranged on a first side of the SiC semiconductor body, and the passivation system is arranged on the insulating layer (locally, a metallization may be arranged in between). The insulating layer has an outer lateral edge on the first side of the SiC semiconductor body, e. g. offset laterally inwards from a lateral edge of the SiC semiconductor body. In an embodiment, an outer lateral edge of the inorganic passivation layer system is arranged on the insulating layer, e. g. offset laterally inwards from the outer lateral edge of the insulating layer.

In other words, the inorganic passivation layer system does not extend down onto the first side of the SiC semiconductor body but ends on the insulating layer. Consequently, e. g. at least in an edge termination region at the lateral edge of the SiC semiconductor body, an interface between the SiC semiconductor body and the insulating layer may be provided instead of an interface between the inorganic passivation layer system and the SiC semiconductor body. Considering for instance a possible SiC oxidation triggered or driven by humidity and electrical fields in this region, the insulating layer as such and/or the interface between the SiC semiconductor body and the insulating layer may be less critical.

The insulating layer, which may comprise one or a plurality of silicon oxide layers (see in detail below), can for instance be less prone to a delamination or crack propagation/transmission than the inorganic passivation layer system, which may comprise for example a silicon nitride layer (see in detail below). The laterally protruding insulating layer can, e.g. in case of a mechanical stress introduced from a SiC oxidation aside or below, reduce a mechanical stress by local cracking, which may reduce a risk of a crack or delamination propagation inwards. For illustration in simplified words, a cracking or local chipping of the outwardly protruding insulating layer may reduce a crack/delamination risk inwards (in direction to the active area). Alternatively or in addition, the interface as such, e.g. silicon oxide/SiC, may have a reduced delamination risk.

Further embodiments and features are provided in the claims and throughout this disclosure. Therein, the individual features shall be disclosed independently of a specific claim category, the disclosure relates to apparatus and device aspects but also to method and use aspects. If for instance a die manufactured in a specific way is described, this is also a disclosure of a respective manufacturing process, and vice versa.

Generally, the SiC semiconductor body may comprise a SiC semiconductor substrate, for instance in combination with one or a plurality of epitaxial SiC layers thereon. That side of an uppermost epitaxial SiC layer, which faces away from the SiC substrate, may be the “first side” of the SiC semiconductor body. Vice versa, that side of the SiC substrate, which faces away from the epitaxial SiC layer or layers, may be the “second side” of the SiC semiconductor body.

Generally, when reference is made to an arrangement of a layer or lateral edge of the layer “on” another layer or entity, e.g. on the SiC semiconductor body, this does not necessarily imply an arrangement directly adjacent to this layer or entity. In other words, an additional layer may be arranged in between, see in further detail below for the arrangement of the inorganic passivation layer system on the insulating layer. Alternatively, an arrangement “on” can mean an arrangement “directly on”, e.g. the outer lateral edge of the insulating layer may also be arranged directly on the first side of the SiC semiconductor body.

In an embodiment, the outer lateral edge of the inorganic passivation layer system is offset laterally inwards from the outer lateral edge of the insulating layer by at least 1 μm, further lower limits being for instance at least 2 μm or 2.5 μm. Possible upper limits can for instance be at most 50 μm, 30 μm or 20 μm. In detail, a respective distance may be taken in a sectional plane perpendicular to the lateral edge of the inorganic passivation layer system, e.g. as smallest lateral distance between the lateral edge of the inorganic passivation layer system and the outer lateral edge of insulating layer. Generally, when reference is made to a “sectional plane”, this may refer to a vertical cross-section parallel to a vertical direction, perpendicular to the lateral directions. The extension of the SiC semiconductor body in the vertical direction may, for instance, be small compared to its extension in the lateral directions.

In an embodiment, the outer lateral edge of the insulating layer is arranged laterally between the lateral edge of the SiC semiconductor body and an active area. In other words, the outer lateral edge of the insulating layer may be arranged in an edge termination region. In an active area, a device structure may be formed in the SiC semiconductor body, see in further detail below.

Near the lateral edge of the SiC semiconductor body, an electrical field may be present, originating for instance from a backside potential which can reach from the backside (second side) to the frontside (first side) at the lateral edge of the SiC semiconductor body and which might trigger or drive oxidation processes. An “outer lateral edge” of the insulating layer or inorganic passivation layer system may face towards the lateral edge of the SiC semiconductor body (whereas an inner lateral edge may oriented towards the active area)

The respective outer lateral edge may for instance be the outermost lateral edge of the insulating layer or inorganic passivation layer or system, e.g. no other element of the insulating layer or inorganic passivation layer system being arranged further outward. Generally, “outward(s)” and “outermost” relate to the lateral position with respect to the respective lateral edge of the SiC semiconductor body, i.e. mean closer or closest to this lateral edge. The elements discussed with respect to their relative position are for instance arranged on the same side of an active area of the die, i.e. at the same lateral edge of the SiC semiconductor body. Therein, similar structures may be arranged at the other lateral edges of the SiC semiconductor body, which, however, is not mandatory.

In the active area, a device structure may be formed in the SiC semiconductor body, comprising for instance a first load terminal arranged at the first side of the SiC semiconductor body. Additionally, the device structure may comprise a second load terminal, e.g. at a vertically opposite second side of the SiC semiconductor body. The device structure can for instance be a FET having a source terminal/region and a drain terminal/region in the SiC semiconductor body, e.g. the source region at the first side of the SiC semiconductor body and the drain region at the second side thereof. In other words, the load pad in the metallization may be a source pad connected to a source terminal of the device structure.

In addition to the source region and the drain region, the device may comprise a body region to which a gate electrode capacitively couples. Additionally, a drift region may be arranged between the body region and the drain region, e.g. made of the same doping type but with a lower concentration than the drain region. The source region and drain region and, if present, drift region may be made of a first doping type, the body region made of a second doping type. In the illustrated embodiments, the first doping type is n-type and the second doping type is p-type.

In an embodiment, independently of a particular device type in the active area, the insulating layer may comprise an oxide layer. The oxide layer may, for example, be an undoped silicate glass (USG) layer, for instance when the device formed in the active area of the die is a diode. Alternatively, the oxide layer may be a phosphosilicate glass (PSG) layer or a borophosphosilicate glass (BPSG) layer, e.g. a BPSG layer with a boron content of 0-5 wt. % (percentage by mass). In other words, the insulating layer may comprise a doped oxide layer, for example in addition to an undoped oxide layer. The insulating layer may for instance have a total thickness of at least 0.3 μm, e.g. at least 0.5 μm, and/or at most 3 μm.

In detail, the insulating layer may comprise an undoped oxide layer, e. g. TEOS layer, which is referred to as “second oxide layer” in the exemplary embodiment. Alternatively or in addition, it may comprise a doped oxide layer, e. g. BPSG layer, which is referred to as “a third oxide layer” in the exemplary embodiment. Optionally, it may comprise an additional oxide layer, for instance below the second and/or third oxide layer and referred to as “first oxide layer” in the exemplary embodiment. The first oxide layer, if present, can for instance be a gate oxide layer, the same layer forming for instance a gate dielectric in the active area.

In an embodiment, the insulating layer comprises the first, second and third oxide layer. For example, the second oxide layer may be arranged directly on the first oxide layer and/or the third oxide layer may be arranged directly on the second oxide layer. In other examples, a further oxide layer may be arranged between the first and second and/or between the second and third oxide layer. In an alternative embodiment, the insulating layer solely comprises the first and third oxide layer (no second oxide layer, for instance), e.g. the third oxide layer arranged directly on the first oxide layer.

By way of example, the third oxide layer may for instance have a thickness of at least 0.2 μm, e. g. at least 0.4 μm, and/or at most 2 μm, e. g. at most 1.2 μm. The second oxide layer, if present, may for instance have a thickness of at least 0.1 μm, e. g. at least 0.15 μm, and/or at most 0.8 μm, e. g. at most 0.6 μm. The first oxide layer, if present, can for instance have a thickness of at least 30 nm, 50 nm, 70 nm or 80 nm, possible upper limits being for instance at most 250 nm, 200 nm or 150 nm.

In an embodiment, the inorganic passivation layer system comprises a silicon nitride layer. Optionally, it may comprise a silicon oxide layer in addition. The silicon nitride layer may be arranged below or on the silicon oxide layer. In an embodiment, the silicon oxide layer is arranged on a first silicon nitride layer, wherein a second silicon nitride layer is arranged on the silicon oxide layer, the silicon oxide layer for instance directly on the first silicon nitride layer and/or the second silicon nitride layer directly on the silicon oxide layer. The first silicon nitride layer may for instance be thinner than the silicon oxide layer and/or second silicon nitride layer. Independently of these geometrical details, the silicon oxide layer may for instance be an undoped silicon oxide layer, e.g. undoped silicon glass (USG).

Independently of the further layer stack or materials in detail, a lowermost layer of the inorganic passivation layer system may be a silicon nitride layer, e. g. first silicon nitride layer in the terminology above. The lowermost layer, e.g. silicon nitride layer, of the inorganic passivation layer system may be arranged directly on the insulating layer or with an additional layer in between. In other words, an additional layer may be arranged in between the inorganic passivation layer system and the insulating layer, e.g. an aluminum oxide layer or a (thin) silicon nitride layer, as discussed in further detail below. For example, only the aluminum oxide layer may be arranged in between the inorganic passivation layer system and the first side of the SiC semiconductor body. The additional layer may for instance serve as an adhesion promoter and/or etch stop layer. It can for instance have a thickness of not more than 30 nm, 20 nm or 15 nm, possible lower limits being for instance 3 nm or 5 nm. Summarized in other words, an arrangement “on” can mean a certain distance, e.g. a comparably small distance of no more than 100 nm, 50 nm, 30 nm, 20 nm or 15 nm, or an arrangement “directly on”.

In an embodiment, the passivation system comprises an organic layer, e. g. an imide layer. The organic layer arranged on the inorganic passivation layer system may be arranged directly on the inorganic passivation layer system or with an additional layer in between, e.g. aluminum oxide layer. Optionally, an outer lateral edge of the organic layer may lie laterally flush with the outer lateral edge of the inorganic passivation layer system. In this case, the organic layer can for instance be used as a mask for structuring the inorganic passivation layer system during manufacturing and remain thereon in the ready-made die.

In an alternative embodiment, the organic layer extends further outwards and covers the outer lateral edge of the inorganic passivation layer system. The organic layer may have its outer lateral edge on the insulating layer, i. e. laterally between the outer lateral edge of the insulating layer and the outer lateral edge of the inorganic passivation layer system. By way of example, the outer lateral edge of the inorganic passivation layer system may be laterally set back under the organic layer by at least 1 μm, further lower limits being for instance at least 2 μm or 2.5 μm. Possible upper limits can for instance be at most 50 μm, 30 μm or 20 μm.

In an alternative embodiment, the organic layer extends further outwards and covers also the outer lateral edge of the insulating layer. In other words, the organic layer has its outer lateral edge on the SiC semiconductor body. The organic layer extending further outwards may for instance reduce or slow down a SiC oxidation, e. g. delay a propagation of humidity towards the interface/first side of the SiC semiconductor body. As discussed above, a SiC oxidation might introduce mechanical stress and cause a delamination risk. By extending the organic layer, e.g. imide layer, above the outer lateral edge of the insulating layer, a SiC oxidation at this geometrically critical location can be at least delayed.

In general words, embodiments of the present application aim at providing an organic layer with an overlap, e.g. laterally outwards, on a lateral edge of an inorganic layer, i.e. covering the lateral edge of the inorganic layer.

In an embodiment, the outer lateral edge of the insulating layer is laterally set back under the organic layer by at least 1 μm, further lower limits being for instance at least 2 μm or 2.5 μm. Possible upper limits can for example be at most 50 μm, 30 μm or 20 μm.

In an embodiment, the organic layer has a thickness of at least 1 μm, further lower limits being for instance at least 2 μm, 3 μm, 4 μm or 5 μm. Possible upper limits may for instance be not more than 50 μm, 40 μm, 30 μm or 25 μm.

In an embodiment, the organic layer is an imide layer. The imide can for instance be a photosensitive polyimide precursor.

In an embodiment, a field reduction structure is formed in the SiC semiconductor body. It may be arranged laterally between the active area and the lateral edge of the SiC semiconductor body. The field reduction structure may lower or reduce an electrical field which reaches up from the backside to the first side, for instance reduce the electrical field towards the active area in which the device structure is arranged. The electrical field reduction structure may comprise a doping well into which a plurality of laterally staggered doping rings are embedded. As viewed for instance in a vertical cross-section perpendicular to the lateral edge of the SiC semiconductor body, the doped rings may be arranged consecutively. As viewed in a vertical top view, they may form rings, one nested in the other. The doping well may have a second doping type, the doped rings having for instance the second doping type as well. As discussed above, the load region or regions of a device structure in the active area, e.g. source and drain region, may have a first doping type.

Independently of these details, the inorganic passivation layer system may cover the electrical field reduction structure vertically upwards. In other words, the outer lateral edge of the inorganic passivation layer system may be arranged on the same lateral position or further outward than an outer lateral end of the field reduction structure, e.g. when viewed in a vertical cross-section perpendicular to the lateral edge of the inorganic passivation layer system. Alternatively or in addition, an inner lateral edge of the inorganic passivation layer system may be arranged on the same lateral position or further inward than an inner lateral end of the field reduction structure, e.g. when viewed in a vertical cross-section perpendicular to the lateral edge of the inorganic passivation layer system.

In an embodiment, the semiconductor die comprises a metallization on the first side of the SiC semiconductor body, an insulating layer as discussed above being for instance arranged between the SiC semiconductor body and the metallization. In case of a FET formed in the semiconductor body, the load pad can for instance be a source pad, see in detail above. The metallization may comprise at least one of copper and aluminum. The metallization may comprise a copper layer or copper layer system, e.g. a bath-deposited copper layer system. As an alternative or in addition, it may comprise an aluminum layer, e.g. a sputter-deposited aluminum layer. The aluminum layer may be Al or AlCu, e.g. with a copper content below 5 wt. %. Below the aluminum layer, a Ti/TiN- and/or NiAl layer or layer stack may be arranged, e.g. a layer stack which solely comprises a Ti/TiN- and NiAl layer.

In an embodiment, the metallization comprises an aluminum layer, e.g. Al or AlCu, having a total thickness of at least 1.5 μm, 2.5 μm or 3 μm, possible upper limits being for instance at most 10 μm, 7 μm or 5 μm. In an alternative embodiment, the metallization comprises an copper layer system, e.g. bath-deposited, having a total thickness of at least 3 μm, 5 μm or 7 μm, possible upper limits being for instance at most 20 μm, 15 μm or 12 μm.

The passivation system may cover a lateral edge of the load pad, e.g. extend aside and reach onto the load pad. The inorganic passivation layer system may extend onto the load pad and cover an outer lateral edge of the load pad, for instance in case of the load pad made of the copper layer system. Alternatively, e.g. in case of a load pad made of the aluminum layer, the inorganic passivation layer system may be arranged aside the load pad, an inner lateral edge of the inorganic passivation layer system being for instance arranged at a distance from an outer lateral edge of the metallization, e.g. of at least 1 μm and/or at most 50 μm, e.g. at least 3 μm and/or at most 10 μm. However, even when the inorganic passivation layer system is arranged aside the load pad, the organic layer may still reach onto the load pad. Therein, independently of whether only the organic layer and/or the inorganic passivation layer system reaches onto the load pad, the passivation system may have an opening on the load pad, e.g. for a later contacting in a package or other mounting structure.

At an outer lateral edge of the load pad, whether made of aluminum or copper, the insulating layer may be arranged below the load pad and the passivation system may be arranged above the load pad, e.g. when viewed in a vertical cross-section perpendicular to the outer lateral edge of the load pad. In other words, the load pad or metallization may, in an area, be arranged vertically between the insulating layer and the passivation system (e.g. organic layer and/or inorganic passivation layer system). In an area further outward, the passivation system may be arranged on the insulating layer without the metallization in between (e.g. apart from a location or locations where a runner is formed). In this area further outward, the inorganic passivation layer system may be arranged on the insulating layer, e.g. at a comparably small distance of no more than 100 nm, 50 nm, 30 nm, 20 nm or 15 nm, or “directly on”, see the description above in detail.

As viewed in a sectional plane perpendicular to the lateral edge of the load pad, the inorganic passivation layer system reaching onto the load pad may have an inner lateral end on the load pad. In general, the organic layer may be flush with the inner lateral end of the inorganic passivation layer system on the load pad. In an embodiment, however, the organic layer extends further inwards than the inorganic passivation layer system, i.e. covers the inner lateral end of the inorganic passivation layer system laterally inwards.

In an embodiment, the inorganic passivation layer system, as viewed in a sectional plane perpendicular to the lateral edge of the load pad, extends uninterrupted, i.e. without an interruption, between the lateral edge of the load pad and the inner lateral end of the inorganic passivation layer system. Alternatively, the inorganic passivation layer system may be provided with an interruption on the load pad, e.g. on a lateral position between the lateral edge of the load pad and the inner lateral end of the inorganic passivation layer system. Independently of whether or not the inorganic passivation layer system is provided with an interruption, the organic layer may extend uninterrupted, i.e. without an interruption between the opening on the load pad and the lateral edge of the load pad (and further outwards towards the lateral edge of the SiC semiconductor body).

In an embodiment, the metallization in the area of the load pad is formed with a step. Laterally outside of the step, e.g. closer to a lateral edge of the SiC semiconductor body or die, the load pad has a first thickness t₁. Laterally inside of the step, e.g. at a larger distance from the lateral edge of the SiC semiconductor body or die, the load pad has a second thickness t₂. Therein, t₁ is smaller than t₂. In other words, the load pad has a smaller thickness t₁ in an edge portion of the load pad and a larger thickness in a central portion of the load pad. The latter may, for example, have advantages in terms of thermal management or mounting and bonding, wherein the smaller thickness in the edge portion can for instance reduce a topology of the passivation system extending onto the load pad.

In an embodiment, an inner lateral position x₂, to which the passivation system extends, is arranged laterally outside of the step. In other words, the passivation system as viewed in the sectional plane extends laterally onto the load pad but ends in the edge region thereof, where the load pad has the thickness t₁. As viewed in a sectional plane, the passivation system covers the lateral edge of the load pad but not the step.

In an embodiment, the metallization comprises a copper layer. The copper layer may be part of a copper layer system which can for instance comprise a sputter-deposited copper layer and one or a plurality of bath-deposited copper layers on top. In an embodiment, the metallization comprises a first bath-deposited copper layer and a second bath-deposited copper layer deposited onto the first bath-deposited copper layer, wherein the second bath-deposited copper layer may be structured with respect to the first bath-deposited copper layer. In other words, the second bath-deposited copper layer may form the step in the load pad.

For a structuring of the second bath-deposited copper layer, a mask may be provided on the first bath-deposited copper layer prior to the deposition of the second bath-deposited copper layer. The step in the load pad can be formed at a lateral edge of the second bath-deposited copper layer, which is displaced inwards with respect to a lateral edge of the first bath-deposited copper layer. Alternatively, however, a copper layer or layers may be sputter-deposited, independently of whether or not a bath-deposited copper layer system is applied subsequently. In other words, a sputter-deposited copper layer or layers may be combined with a bath-deposited copper layer(s) or the copper metallization as a whole may be sputter-deposited. Also in case of the sputter-deposited copper metallization, an upper copper layer may be structured with respect to a copper layer below to form a step.

In sum, independently of whether sputter-and/or bath-deposited, all copper layers of the metallization can for instance have a thickness of at least 3 μm, further lower limits being for instance 5 μm or 7 μm. By way of example, upper limits may be 25 μm or 20 μm. Below the lowermost copper layer, e.g. sputter-deposited copper layer, a barrier layer system of the metallization may be arranged (e.g. comprising a Ti/TiN layer).

Above the insulating layer and/or below the organic layer, e.g. vertically between the insulating layer and the organic layer, an adhesion promoter layer may be provided. The adhesion promoter layer may have a thickness of at least 10 μm and/or at most 100 μm, further upper limits being for instance at most 70 μm or 50 μm. The adhesion promoter layer may be an inorganic layer, e.g. a silicon nitride layer. In comparison to the inorganic passivation layer system, the adhesion promoter layer may, e.g. seen in a vertical cross-section perpendicular to the outer lateral edge of the insulating layer, extend further inward and/or further outward.

Where the inorganic passivation layer system is formed on the insulating layer, the adhesion promoter layer may be arranged vertically between the insulating layer and the inorganic passivation layer system. Where the metallization, e.g. load pad, extends on/onto the insulating layer, the adhesion promoter layer may cover at least a part of the metallization/load pad, e.g. be arranged vertically between the load pad/metallization and the organic layer. Laterally inwards on the metallization/load pad, the adhesion promoter layer may, for example, reach as far as the passivation system reaches, e.g. up to an opening which the organic layer has on the load pad/metallization.

A method of manufacturing a semiconductor die may comprise:
I) forming an insulating layer on a first side of a silicon carbide (SiC) semiconductor body, so that an outer lateral edge of the insulating layer is arranged on the SiC semiconductor body;
II) forming an inorganic passivation layer system on the insulating layer, so that an outer lateral edge of the inorganic passivation layer system is arranged on the insulating layer and is offset laterally inwards from the outer lateral edge of the insulating layer.

In an embodiment, step II) comprises:
i) depositing the inorganic passivation layer system on the first side of the SiC semiconductor body;
ii) etching away the inorganic passivation layer system locally to define the outer lateral edge of the inorganic passivation layer system.

For step ii), a mask may be deposited on the inorganic passivation layer system. The inorganic passivation layer system may be etched away locally where the mask has an opening, for example on the insulating layer and/or on a load pad formed in a metallization. Independently of these details, the mask may be removed after the inorganic passivation layer system has been etched away locally, e.g. prior to forming the organic layer in step II).

Any of these methods or method steps discussed above may be applied for manufacturing a semiconductor die discussed above.

### BRIEF DESCRIPTION OF THE DRAWINGS

Below, the semiconductor die and method of manufacturing are explained in further detail by means of exemplary embodiments. Therein, the individual features can also be relevant in a different combination.

FIG. 1 shows a cross-sectional view of a semiconductor die comprising a SiC semiconductor body and a passivation system;

FIG. 2 shows a more detailed view of a passivation system on a SiC semiconductor body;

FIG. 3 shows a schematic cross-section of a device formed in an active area of a semiconductor die;

FIGS. 4a-e illustrate different steps of manufacturing a semiconductor die with a passivation system comprising an inorganic passivation layer system and an organic layer;

FIG. 5 shows a detailed view of an embodiment of a passivation system on a SiC semiconductor body;

FIG. 6 summarizes some manufacturing steps in a flow diagram;

FIG. 7 shows a cross-sectional view of a semiconductor die comprising a SiC semiconductor body, an insulating layer and a passivation system;

FIGS. 8a-e illustrate schematic cross-sectional views of different embodiments of a SiC semiconductor body with an insulating layer and a passivation system;

FIG. 9 summarizes some manufacturing steps in a flow diagram;

FIG. 10 shows a cross-sectional view of a semiconductor die comprising a SiC semiconductor body and a passivation system.

### DETAILED DESCRIPTION

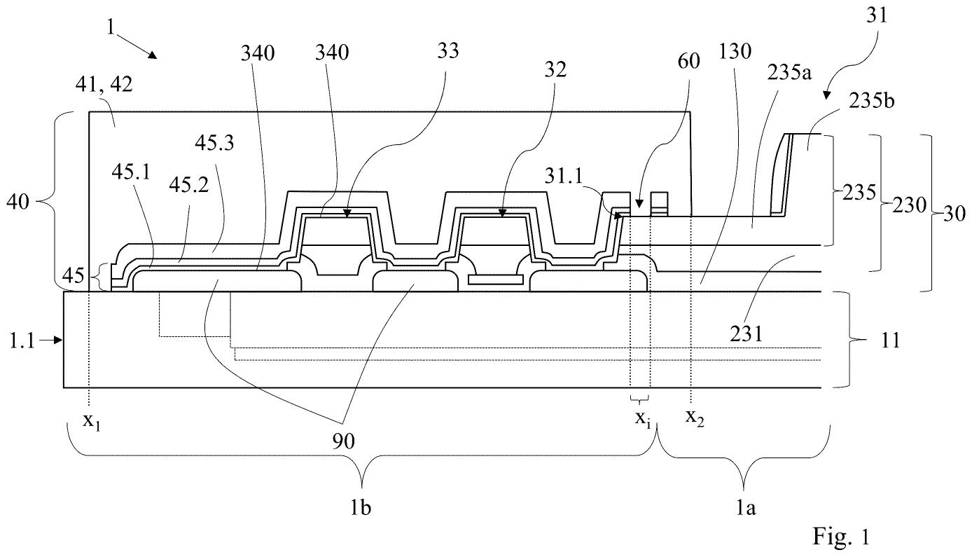

FIG. 1 shows a portion of a semiconductor die 1 in a vertical cross-section. The semiconductor die 1 comprises a silicon carbide (SiC) semiconductor body 11. On a first side 11.1 of the SiC semiconductor body 11, an insulating layer 90 is arranged. Further, a metallization 30 is formed on the SiC semiconductor body 11, which comprises a barrier layer system 130. On the barrier layer system 130, a copper layer system 230 is arranged, which in the example shown comprises a sputter-deposited copper layer 231 and a bath-deposited copper layer system 235 with a first bath-deposited copper layer 235a and a second bath-deposited copper layer 235b.

In detail, the cross-sectional view of FIG. 1 lies at a lateral edge 1.1 of the die 1, wherein an inactive area 1b is arranged laterally between the lateral edge 1.1 of the die 1 and an active area 1a shown on the right in FIG. 1. In the active area 1a, transistor device cells may be arranged (see in detail below). In the active area 1a, a load pad 31 may be formed in the metallization 30, for example a source pad connected to a source terminal of the device or device cells. In the inactive area 1b, a gate runner 32 and/or a source runner 33, each extending along the active area 1a, may be formed in the metallization 30.

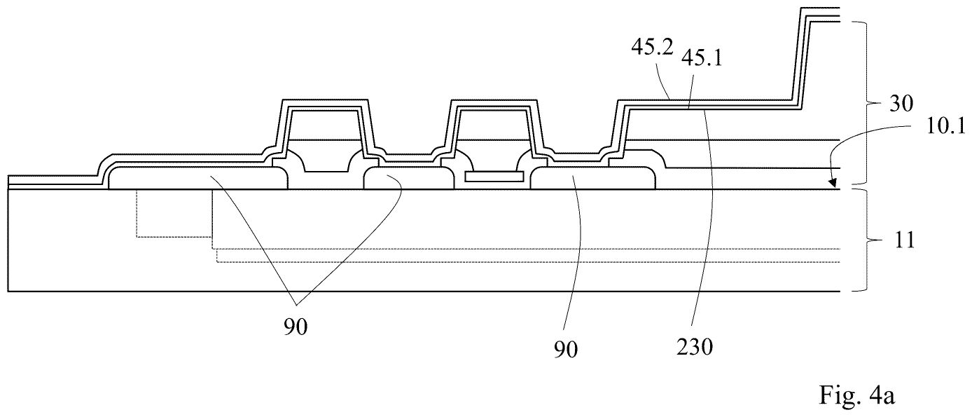

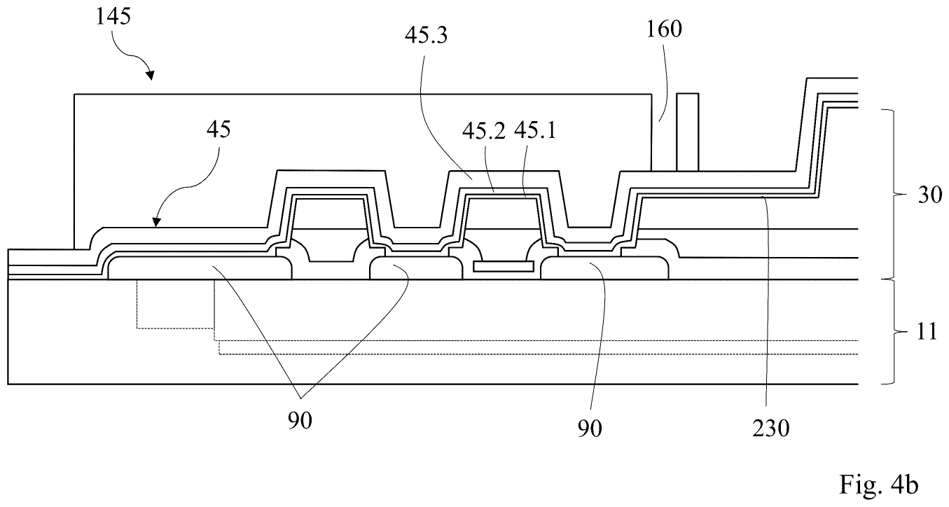

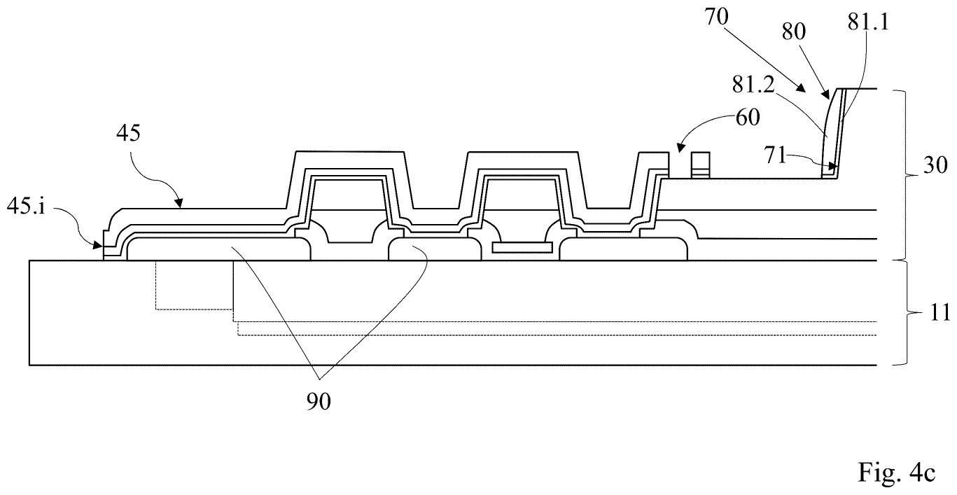

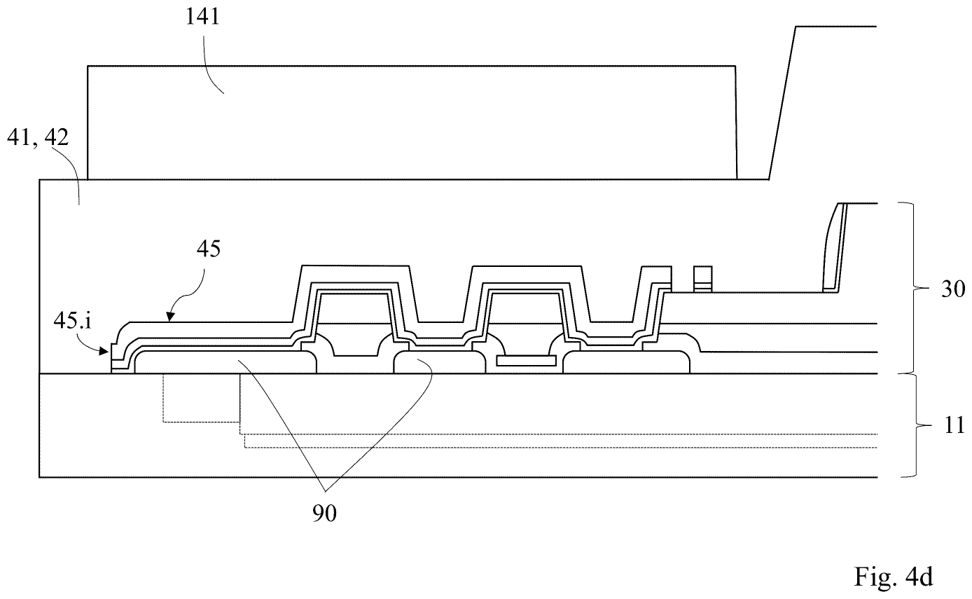

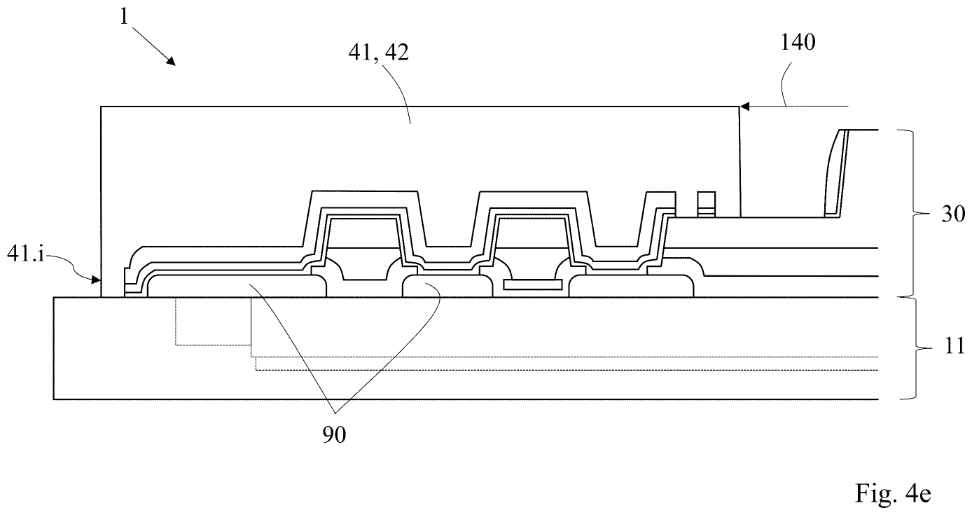

On the metallization 30, a passivation system 40 is arranged, which in the example shown comprises an inorganic passivation layer system 45 and an organic layer 41, e.g. imide layer 42, on the inorganic passivation layer system 45. As discussed in further detail with reference to FIG. 4e, an additional adhesion promoter layer can be arranged in between (not shown here).

The inorganic passivation layer system 45 shown comprises a first silicon nitride layer 45.1, an undoped silicon oxide layer 45.2 directly on the first silicon nitride layer 45.1, and a second silicon nitride layer 45.3 directly on the undoped silicon oxide layer 45.2. The passivation system 40 covers the gate runner 32 and source runner 33 and covers also the insulating layer 90 made of doped oxide (e.g. borophosphosilicate glass, BPSG). In the example shown, an aluminum oxide layer 340 (shown only as a line in FIG. 1) is arranged below the inorganic passivation layer system 45, i.e. on the insulating layer 90 and also on the metallization 30.

The sectional plane of FIG. 1 lies perpendicular to a lateral edge 31.1 of the load pad 31. The passivation system 40 extends between an outer lateral position x₁ aside the load pad and an inner lateral position x₂ which lies on the load pad 31, i.e. covers the lateral edge 31.1 of the load pad 31. In the embodiment shown, an interruption 60 is provided in at least one layer 41, 42, 45.1-45.3 of the passivation system 40, in this case the interruption 60 intersects the inorganic passivation layer system 45 completely. It is arranged at an interruption position xᵢ laterally between the lateral edge 31.1 of the load pad 31 and the inner lateral position x₂.

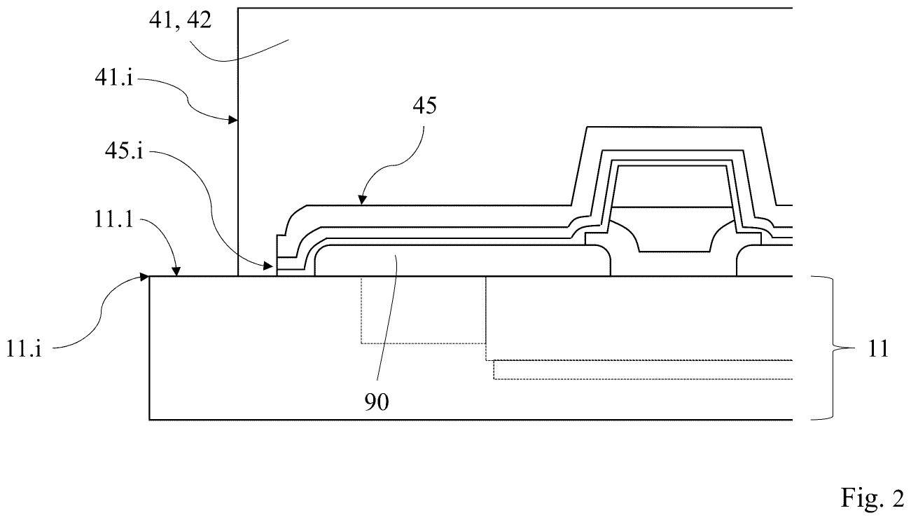

FIG. 2 shows a more detailed view of a lateral edge 45.i of the inorganic passivation layer system 45, which is arranged on the SiC semiconductor body 11, wherein the sectional plane lies perpendicular to this lateral edge 45.i. The lateral edge 45.i of the inorganic passivation layer system 45 is offset inwards from a lateral edge 11.i of the SiC semiconductor body 11. The organic layer 41, e.g. imide layer 42 in the example shown, extends further outwards and covers the lateral edge 45.i of the inorganic passivation layer system 45. Consequently, an outer lateral edge 41.i of the organic layer 41 is arranged further outward, i.e. closer to the lateral edge 11.i of the SiC semiconductor body 11, than the lateral edge 45.i of the inorganic passivation layer system 45.

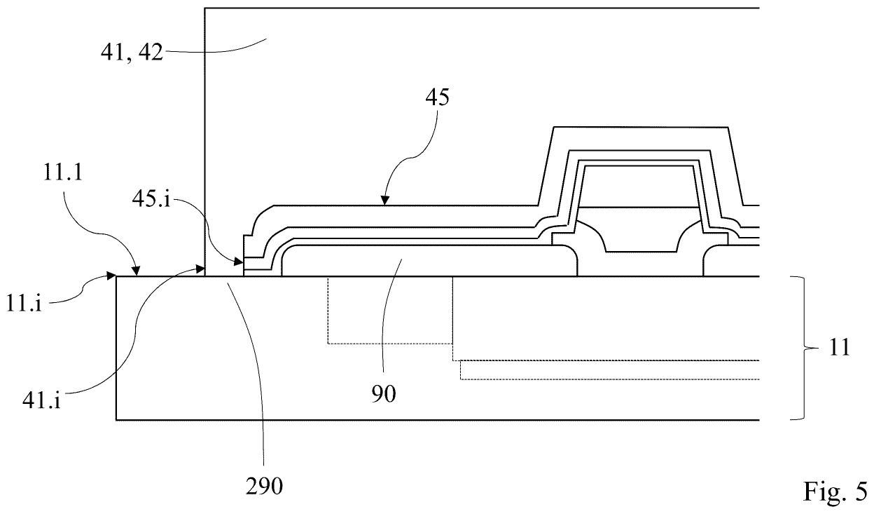

In the example shown, the inorganic passivation layer system 45, i.e. the first silicon nitride layer 45.1, and the organic layer 41 are respectively arranged directly on the first side 11.1 of the SiC semiconductor body 11, namely the inorganic passivation layer system 45 laterally outside of the insulating layer 90 and the organic layer 41 laterally outside of the lateral edge 45.i of the inorganic passivation layer system. Alternatively, however, an additional layer may be arranged in between, e.g. an aluminum oxide layer (see FIG. 5 for illustration).

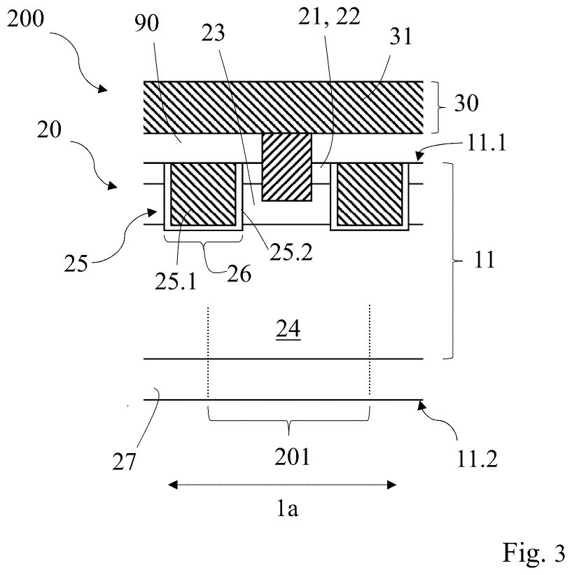

FIG. 3 illustrates a possible device 200 and device structure 20 formed in the active area 1a of the die 1, e.g. below the load pad 31 (see FIG. 1 for comparison). In the SiC semiconductor body 11, a load terminal 21 is formed at the first side 11.1, which is a source region 22 in the example shown. At the vertically opposite second side 11.2, a drain region 27 is arranged, wherein a body region 23 disposed below the source region 22 and a drift region 24 is arranged between the body region 23 and the drain region 27.

A gate region 25 comprising a gate electrode 25.1 and a gate dielectric 25.2 capacitively coupling the gate electrode 25.1 to the body region 23 is arranged in a trench 26. Via a voltage applied to the gate electrode 25.1, a channel formation in the body region 23 and, in consequence, current flow between the source region 22 and drain region 25 can be controlled. The device 200 may comprise a plurality of device cells 201 connected in parallel.

FIGS. 4a-e illustrate some steps for manufacturing a semiconductor die having a semiconductor body, and a metallization and a passivation system. In FIG. 4a, the insulating layer 90 has already been deposited onto the first side 11.1 of the semiconductor body 11 and the metallization 30 has been formed. Onto the metallization 30, the aluminum oxide layer 230 has been deposited (shown only as a line) and the silicon nitride layer 45.1 and the silicon oxide layer 45.2 have been deposited.

Prior to covering the silicon oxide layer 45.2 by the second silicon nitride layer 45.3 as shown in FIG. 4b, the silicon oxide layer 45.2 may be etched back (not shown in detail here). In FIG. 4b, the inorganic passivation layer system 45 has been deposited but not structured yet. For that purpose, a mask 145 is provided on the inorganic passivation layer system 45. The mask 145 has an opening 160 defining where the interruption is to be etched into the inorganic passivation layer system 45. Further, the mask 145 defines an inner and outer lateral end of the inorganic passivation layer system 45, i.e. where the inorganic passivation layer system 45 is to be opened on the load pad 31.

FIG. 4c illustrates the inorganic passivation layer system 45 after the etch step, i.e. after the interruption 60 has been etched into the inorganic passivation layer system 45 and the lateral edge 45.i of the inorganic passivation layer system 45 has been defined. E.g. applying an anisotropic etch step may leave inorganic layers 81.1, 81.2, e.g. a stack 80 of inorganic layers 81.1, 81.2, on the flank 71 of the step 70.

In a subsequent step illustrated in FIG. 4d, the organic layer 41, e.g. imide layer 42 in the example shown, has been deposited onto the structured inorganic passivation layer system 45. For a structuring of the organic layer 41, a mask 141 is formed on the organic layer 41. The mask 141 defines the lateral edge 41.i and the opening 140 in the organic layer 41, see FIG. 4e for illustration. In this process step, the organic layer 41 has been etched back and the mask has been removed from the organic layer 41.

FIG. 5 shows a detailed view of a lateral edge 11.i of the SiC semiconductor body 11. The embodiment shown in FIG. 5 differs from the embodiment illustrated in FIG. 2 in that the inorganic passivation layer system 45 and the organic layer 41, e.g. imide layer 42, are not arranged directly on the first side 11.1 of the SiC semiconductor body 11 laterally outside of the insulating layer 90. Instead, an adhesion promoter or etch stop layer 290 is arranged in between, which is an aluminum oxide layer in the example shown.

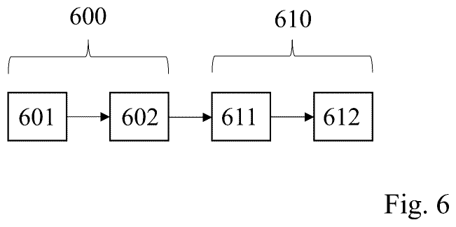

FIG. 6 summarizes some manufacturing steps in a flow diagram. Forming 600 an inorganic passivation layer system on a first side of a SiC semiconductor body may comprise depositing 601 the inorganic passivation layer system on the first side, wherein the inorganic passivation layer system is subsequently etched away 602 locally to define a lateral edge of the inorganic passivation layer system. Subsequently, the organic layer may be formed 610, e.g. by depositing 611 the organic layer and etching it away 612 locally to define an opening and a lateral edge.

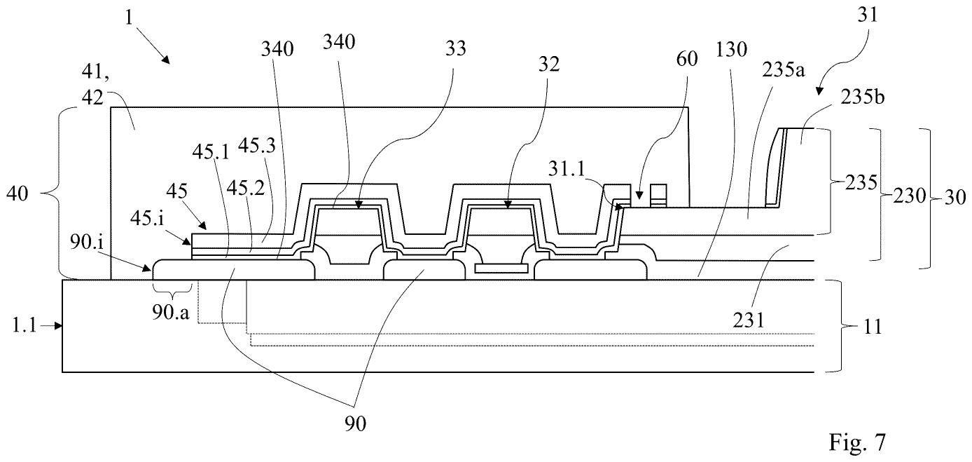

FIG. 7 shows an embodiment which differs partly from the one discussed with reference to FIG. 1. Also in this case, an insulating layer 90, a metallization 30 and a passivation system 40 are arranged on the first side 11.1 of the SiC semiconductor body 11 (see the description above for further details). In contrast to FIG. 1, the outer lateral edge 45.i of the inorganic passivation layer system 45 is not arranged aside the insulating layer 90, but on the insulating layer 90. Consequently, a portion 90a of the insulating layer 90 aside the outer lateral edge 45.i of the inorganic passivation layer system 45, i.e. between the outer lateral edge 45.i of the inorganic passivation layer system 45 and the outer lateral edge 90.i of the insulating layer 90, is not covered by the inorganic passivation layer system 45.

The organic layer 41, e.g. imide layer 42, extends further outwards, i.e. in direction to the outer lateral edge 1.1 of the die 1, than the inorganic passivation layer system 45 and the insulating layer 90. It covers the outer lateral edge 45.i of the inorganic passivation layer system 45 and also the outer lateral edge 90.i of the insulating layer 90.

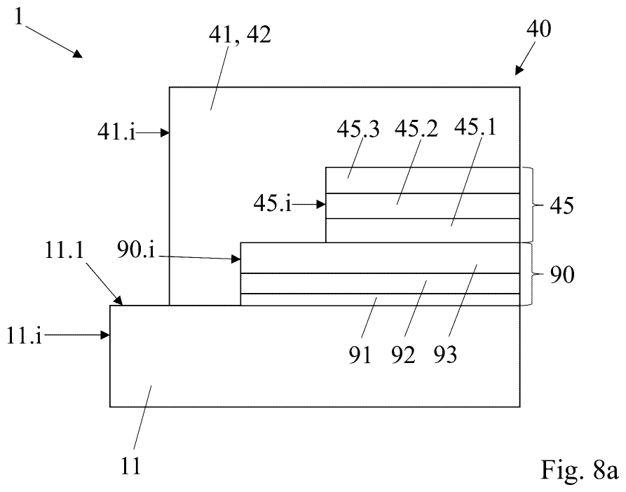

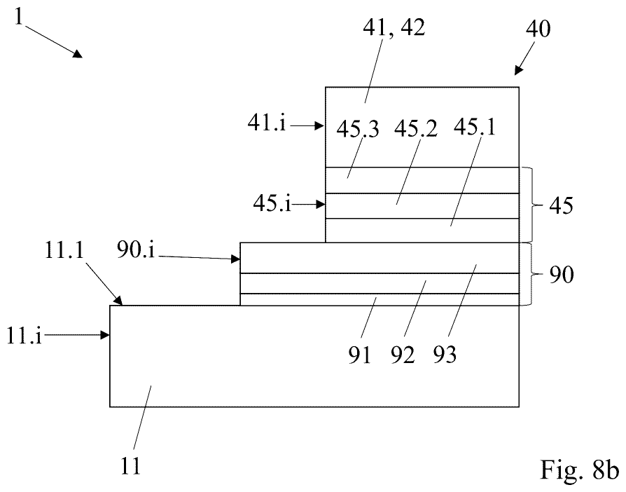

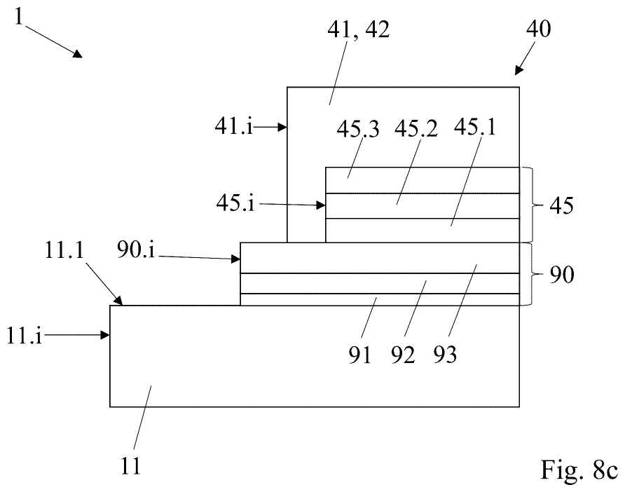

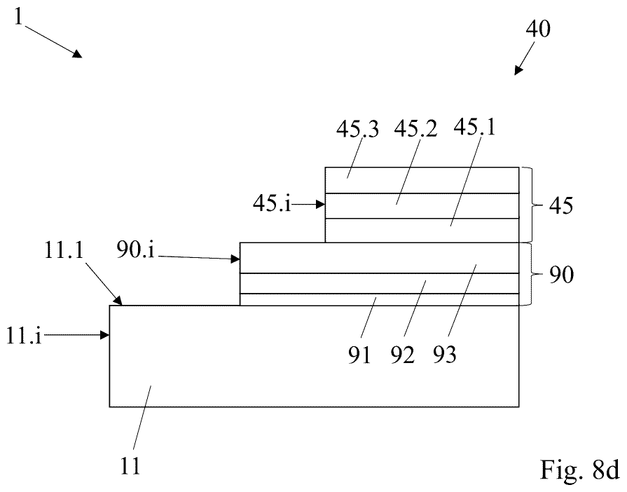

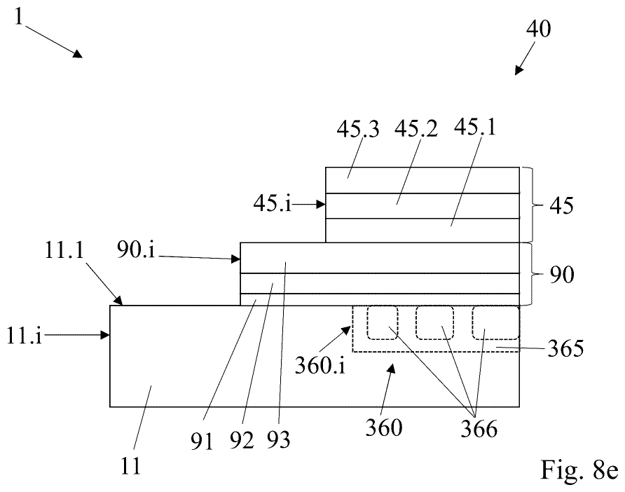

The embodiment shown in FIG. 8a corresponds basically to the one of FIG. 7, wherein FIG. 8a shows a smaller portion of the die 1. The insulating layer 90 is arranged on the first side 11.1 of the SiC semiconductor body 11, e. g. directly on the first side 11.1. In the example shown, it comprises a first oxide layer 91, a second oxide layer 92 and a third oxide layer 93, wherein the first and second oxide layers 91, 92 are undoped and the third oxide layer 93 is doped. In detail, the third oxide layer 93 may be a BPSG layer, the second oxide layer 92 may be a TEOS layer (tetraethoxysilane) and the first oxide layer 91 may be a gate oxide layer, e. g. or serving as a gate dielectric in the active area of the die 1.

Independently of these details, the insulating layer 90 has an outer lateral edge 90.i on the first side 11.1 of the SiC semiconductor body 11, the outer lateral edge 90.i being offset inwards from the outer lateral edge 11.1 of the SiC semiconductor body 11. Further, a passivation system 40 comprising an inorganic passivation layer system 45 is arranged on the insulating layer 90, e.g. directly thereon or with an aluminum oxide layer (not shown here) in between. As illustrated for instance in FIGS. 1, 2, 4, 5 and 7, a metallization may be arranged between the insulating layer 90 and the inorganic passivation layer system 45 in other portions of the die 1 (e. g. where the gate and/or source runner are formed and/or at the lateral edge of the load pad).

In the example of FIG. 8a, the inorganic passivation layer system 45 comprises a first silicon nitride layer 45.1, an undoped silicon oxide layer 45.2 directly on the first silicon nitride layer 45.1, and a second silicon nitride layer 45.3 directly on the undoped silicon oxide layer 45.2. Independently of this layer stack in detail, the inorganic passivation layer system 45 has an outer lateral edge 45.i on the insulating layer 90. In other words, the outer lateral edge 45.i of the inorganic passivation layer system 45 is offset inwards from the outer lateral edge 90.i of the insulating layer 90, and the outer lateral edge 90.i of the insulating layer 90 is offset inwards from the lateral edge 11.i of the SiC semiconductor body 11.

In addition to the inorganic passivation layer system 45, the passivation system 40 of FIG. 8a comprises an organic layer 41, e. g. an imide layer 42. In this embodiment, the organic layer 41 covers the outer lateral edge 45.i of the inorganic passivation layer system 45 and the outer lateral edge 90.i of the insulating layer 90, i. e. extends further outwards than the inorganic passivation layer system 45 and also than the insulating layer 90. An outer lateral edge 41.i of the organic layer 41 is arranged on the first side 11.1 of the SiC semiconductor body 11, e. g. directly on or with an aluminum oxide layer in between.

In the embodiment shown in FIG. 8b, the insulating layer 90 and the inorganic passivation layer system 45 are arranged as discussed with reference to FIG. 8a. However, the embodiment differs as to the extension of the organic layer 41, because the outer lateral edge 41.i thereof is not arranged outside the outer lateral edge 90.i of the insulating layer 90 but lies laterally flush with the outer lateral edge 45.i of the inorganic passivation layer system 45. During manufacturing, the organic layer 41 can for instance be used as an etch mask for structuring the inorganic passivation layer system 45, and it can remain on the inorganic passivation layer system 45 in the ready-made die.

In the embodiment shown in FIG. 8c, the organic layer 41 extends further outwards than the inorganic passivation layer system 45, the latter being for instance structured with a separate mask which is removed prior to the deposition of the organic layer 41. In contrast to FIG. 8 a, the outer lateral edge 41.i of the organic layer 41 is offset inwards from the outer lateral edge 90.i of the insulating layer 90. It is arranged laterally between the outer lateral edge 90.i of the insulating layer 90 and the outer lateral edge 45.i of the inorganic passivation layer system 45.

FIG. 8d illustrates a further embodiment, wherein the passivation system 40 comprises an inorganic passivation layer system 45 but no organic layer. The outer lateral edge 45.i of the inorganic passivation layer system 45 is arranged on the insulating layer 90, see the description above.

FIG. 8e illustrates another embodiment, wherein the passivation system 40 corresponds to the embodiment shown in FIG. 8d. However, FIG. 8e additionally illustrates a field reduction structure 360 which is formed in the SiC semiconductor body 11. It comprises a doping well 365, into which a plurality of laterally staggered doped rings 366 are embedded, so that a doping concentration decreases stepwise towards the lateral edge 11.i of the SiC semiconductor body 11.

As discussed above, the outer lateral edge 45.i of the inorganic passivation layer system 45 is arranged on the insulating layer 90, i.e. is offset laterally inwards from the outer lateral edge 90.i of the insulating layer 90. Therein, the inorganic passivation layer system 45 still covers the field reduction structure 360 vertically upwards. In the example shown, the outer lateral edge 45.i of the inorganic passivation layer system 45 is arranged further outward than an outer lateral edge 360.i of the field production structure 360.

A field reduction structure 360 as shown in FIG. 8e may be implemented in any of the embodiments shown in FIGS. 8a-d, i.e. in combination with an organic layer 41, e.g. imide layer 42, and independently of where the outer lateral edge 41.i of the organic layer 41 is arranged.

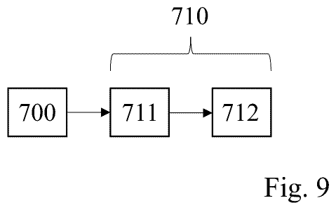

FIG. 9 summarizes some manufacturing steps in a flow diagram. After forming 700 an insulating layer on the first side of the SiC semiconductor body, an inorganic passivation layer system 45 may be formed 710 (in between, a metallization may be formed). Forming 710 the inorganic passivation layer system may comprise depositing 711 the inorganic passivation layer system on the first side of the SiC semiconductor body and etching it away 712 locally to define the outer lateral edge.

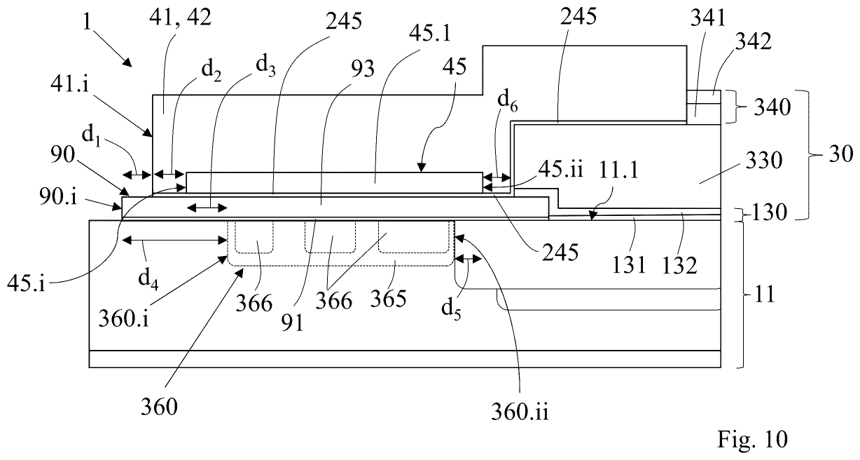

FIG. 10 shows a semiconductor die 1 in a vertical cross-section. On a first side 11.1 of the SiC semiconductor body 11, an insulating layer 90 is arranged. In the example shown, the insulating layer 90 comprises a first oxide layer 91, which is an undoped oxide, e.g. formed as a gate oxide layer. The insulating layer 90 further comprises a third oxide layer 93, which may be a silicon glass layer, e.g. USG, PSG or BPSG layer. In contrast to the embodiments above, no second oxide layer is arranged between the first and the third oxide layer 91, 93. In other words, the third oxide layer 93 is arranged on, e.g. directly on, the first oxide layer 91.

The inorganic passivation layer system 45 shown in FIG. 10 comprises a first silicon nitride layer 45.1 which is disposed on an adhesion promoter layer 245. The adhesion promoter layer 245 may be a silicon nitride layer as well, e.g. with a thickness of 10-100 μm. It extends below the first silicon nitride layer 45.1 and further laterally aside, e.g. to improve an adhesion of the organic layer 41 on the insulating layer 90 and/or on the metallization 30. Apart from the first silicon nitride layer 45.1, the inorganic passivation layer system 45 shown comprises no additional layer.

An outer lateral edge 45.i of the inorganic passivation layer system 45 is arranged on the insulating layer 90. As discussed in detail for the embodiment of FIG. 8c, an outer lateral edge 41.i of the organic layer 41 is arranged on the insulating layer 90 as well, i.e. laterally between the outer lateral edge 90.i of the insulating layer 90 and the outer lateral edge 45.i of the inorganic passivation layer system 45. In the embodiment of FIG. 10, a first lateral distance d₁ between the outer lateral edges 90.i, 41.i of the insulating layer 90 and the inorganic layer 41 is between 1-20 μm, e.g. 3-10 μm, and a second lateral distance d₂ between the outer lateral edges 41.i, 45.i of the organic layer 41 and the inorganic passivation layer system 45 is between 1-20 μm, e.g. 3-10 μm, as well.

In the SiC semiconductor body 11, a field reduction structure 360 is arranged. It comprises a doping well 365, into which a plurality of laterally stacked doped rings 366 are embedded. In the example shown, the doping well 365 and the doped rings 366 have a second doping type, which may be p-type.

The inorganic passivation layer system 45 covers the field reduction structure 360 vertically upwards. The outer lateral end 360.i of the field reduction structure 360 is arranged laterally inside of the outer lateral edge 45.i of the inorganic passivation layer system 45, and an inner lateral end 360.ii of the field reduction structure is arranged laterally outside of an inner lateral edge 45.ii of the inorganic passivation layer system 45. In the example shown, a third lateral distance d₃ between the outer lateral edge 45.i and the outer lateral end 360.i is between 10-40 μm, e.g. 20-30 μm, and a fourth lateral distance d₄ between the outer lateral edge 90.i and outer lateral end 360.i is between 20-50 μm, e.g. 30-40 μm. A fifth lateral distance d₅ between the inner lateral edge 45.ii and the inner lateral end 360.ii is between 1-20 μm, e.g. 3-10 μm, and a sixth lateral distance d₆ between the inner lateral edge 45.ii and the metallization 30 is between 1-20 μm, e.g. 3-10 μm.

The metallization 30 shown in FIG. 10 comprises a barrier layer system 130, e.g. with a first layer 131 and a second layer 132. The first and/or second layer 131, 132 may respectively comprise at least one of Ti, TiN, Ta, TaN, TiW, W or NiAl. On the barrier layer system 130, an aluminum or copper layer 330 is arranged, e.g. made of AlCu in the example of FIG. 10. On the aluminum or copper layer 330, a layer stack 340 is arranged, which comprises one or more layers, e.g. a first layer 341 and a second layer 342. The first and/or second layer 341, 342 may respectively comprise at least one of Pd, NiP, Au or Ag.

1. A semiconductor die, comprising:
a silicon carbide (SiC) semiconductor body;
an insulating layer on a first side of the SiC semiconductor body; and
a passivation system on the insulating layer, wherein the passivation system comprises an inorganic passivation layer system, wherein the insulating layer has an outer lateral edge on the SiC semiconductor body, wherein an outer lateral edge of the inorganic passivation layer system is arranged on the insulating layer and is offset laterally inwards from the outer lateral edge of the insulating layer.

2. The semiconductor die of claim 1, wherein the outer lateral edge of the inorganic passivation layer system is offset laterally inwards by at least one of at least 1 μm or at most 50 μm from the outer lateral edge of the insulating layer.

3. The semiconductor die of claim 1, wherein the outer lateral edge of the insulating layer is arranged between a lateral edge of the SiC semiconductor body and an active area of the semiconductor die.

4. The semiconductor die of claim 1, wherein the insulating layer comprises a silicon oxide layer.

5. The semiconductor die of claim 4, wherein the insulating layer comprises at least one of an undoped oxide layer or a doped oxide layer.

6. The semiconductor die of claim 1, wherein the insulating layer has a total thickness of at least one of at least 0.3 μm or at most 3 μm.

7. The semiconductor die of claim 1, wherein the inorganic passivation layer system comprises a silicon nitride layer.

8. The semiconductor die of claim 1, wherein the passivation system comprises an organic layer on the inorganic passivation layer system.

9. The semiconductor die of claim 8, wherein the outer lateral edge of the inorganic passivation layer system is covered by the organic layer, the organic layer having an outer lateral edge on the insulating layer.

10. The semiconductor die of claim 9, wherein the outer lateral edge of the inorganic passivation layer system is laterally set back under the organic layer by at least 1 μm.

11. The semiconductor die of claim 8, wherein the outer lateral edge of the inorganic passivation layer system and the outer lateral edge of the insulating layer are covered by the organic layer, the organic layer having an outer lateral edge on the SiC semiconductor body.

12. The semiconductor die of claim 11, wherein the outer lateral edge of the insulating layer is laterally set back under the organic layer by at least 1 μm.

13. The semiconductor die of claim 1, wherein a field reduction structure is formed in the SiC semiconductor body, the inorganic passivation layer system covering the field reduction structure vertically upwards.

14. A method of manufacturing a semiconductor die, comprising:
forming an insulating layer on a first side of a silicon carbide (SiC) semiconductor body, so that an outer lateral edge of the insulating layer is arranged on the SiC semiconductor body; and
forming an inorganic passivation layer system on the insulating layer, so that an outer lateral edge of the inorganic passivation layer system is arranged on the insulating layer and is offset laterally inwards from the outer lateral edge of the insulating layer.

15. The method of claim 14, wherein forming the inorganic passivation layer system on the insulating layer comprises:
depositing the inorganic passivation layer system on the first side of the SiC semiconductor body.

16. The method of claim 15, wherein forming the inorganic passivation layer system on the insulating layer comprises:
etching away the inorganic passivation layer system locally to define the outer lateral edge of the inorganic passivation layer system.

17. A semiconductor die, comprising:
a silicon carbide (SiC) semiconductor body;
an insulating layer on a first side of the SiC semiconductor body; and
a passivation system on the insulating layer, wherein the passivation system comprises an inorganic passivation layer system, wherein the insulating layer has an outer lateral edge on the SiC semiconductor body, wherein an outer lateral edge of the inorganic passivation layer system is arranged on the insulating layer.

18. The semiconductor die of claim 17, wherein the outer lateral edge of the inorganic passivation layer system is offset laterally inwards by at least one of at least 1 μm or at most 50 μm from the outer lateral edge of the insulating layer.

19. The semiconductor die of claim 17, wherein the outer lateral edge of the insulating layer is arranged between a lateral edge of the SiC semiconductor body and an active area of the semiconductor die.

20. The semiconductor die of claim 17, wherein the insulating layer comprises a silicon oxide layer.
